(19) United States
(12) Patent Application Publication
(10) Pub. No.: US 2026/0051889 A1
(43) Pub. Date: Feb. 19, 2026

(54) COMMON-SOURCE CONFIGURATION OF TWO TRANSISTORS

(71) Applicant: Siemens Aktiengesellschaft

(72) Inventors: Julian Stefan Breiter, Regensburg (DE); Karsten Handt, Berg (DE); Hauke Nannen, Nürnberg (DE)

(21) Appl. No.: 19/299,602

(22) Filed: Aug. 14, 2025

(30) Foreign Application Priority Data
Aug. 14, 2024 (DE) 10 2024 207 757.7

(51) Int. Cl. H03K 17/687

(52) U.S. Cl. CPC H03K 17/6871

(57) ABSTRACT

A common-source configuration of two transistors, each having a source terminal, a sink terminal and a control terminal, has two control circuits for controlling one of the transistors each, to control a load current through the configuration. The configuration has a main current path for the load current, and an auxiliary current path for the load current which runs parallel to a section of the main current path. A control series resistor is arranged in one of the control circuits in the auxiliary current path. The source terminals are electrically connected, and the two sink terminals and the two source terminals are in the main current path. Running parallel to a section of the main current path is the auxiliary current path, one half of which is formed by a section of the first control circuit and the other half is formed by a section of the second control circuit.

### CROSS-REFERENCE TO RELATED APPLICATION

This application claims the priority, under 35 U.S.C. § 119, of German Patent Application DE 10 2024 207 757.7, filed Aug. 14, 2024; the prior application is herewith incorporated by reference in its entirety.

### FIELD AND BACKGROUND OF THE INVENTION

The present invention relates to a common-source configuration of two transistors.

### TECHNICAL BACKGROUND

MOSFETs are known which, in addition to the drain pin or terminal, the source pin and the gate pin, also have a further pin, the so-called “Kelvin pin”, see FIG. 1 and FIG. 9. This fourth pin allows the gate control circuit to pass the inductance of the source pin and therefore to decouple the gate control, i.e. the gate control circuit, from the load circuit, allowing an increase in the switching speed and a decrease in the required switching energy and therefore a significant improvement in the switching behavior. Since the additional Kelvin pin has many advantages, manufacturers of semiconductor devices equip more and more MOSFETs with a Kelvin pin and in some cases no longer offer MOSFETs with only three pins for the drain, source and gate, as shown in FIG. 10, for the standard housing (through-hole package) TO-247. Since both the Kelvin pin and the source pin inside the transistor on the “bare die” are connected to the source terminal of the transistor, the Kelvin pin can also be referred to as a Kelvin source terminal or pin, or as an auxiliary source terminal or pin, and the source pin can be referred to as a power source terminal or pin to better distinguish the Kelvin pin. The term “power source terminal” or “power source pin” is therefore used because the load current flows through this terminal, whereas the significantly lower gate control current flows through the Kelvin source terminal.

A description of this issue can be found in the journal article “Potenzial von SiC voll ausschöpfen. SMD-MOSFETs mit Kelvin-Source-Pin [Making Full Use of the Potential of SiC. SMD MOSFETs with a Kelvin Source Pin]” in the journal “emobility tec”, issue January 2019, authors: Christian Felgemacher, Felipe Filsecker, Farhan Beg, Aly Mashaly, Seiya Kitagawa, pages 14-17, Hüthig Medien GmbH, Heidelberg, Germany, 2019, https://www.rohm.de/documents/4392907/6355683/emobilitytec_0119_080319 Coverstory.pdf/ed87c1ee-02e2-a6ce-5f27-6785fd8405b5?t=1586410136257 (retrieved online on 03.13.2024).

Not only MOSFETs, but also other types of transistors, can have such a fourth pin. For example, FIG. 12 shows a 4-pin IGBT with a diode connected in parallel, compared to a 3-pin IGBT with a diode connected in parallel shown in FIG. 11. In an IGBT, the fourth pin is referred to as the Kelvin emitter.

Further information on this issue can also be found in the publication “TRENCHSTOP™ 5 IGBT in a Kelvin Emitter Configuration. Performance Comparison and Design Guidelines”, Application Note, Revision 1.0, date 2014 Oct. 16, 12 pages, Infineon Technologies AG, Munich, Germany, 2014, https://www.infineon.com/dgdl/Infineon-TRENCHSTOP5_in_TO-247-4pin-ApplicationNotes-v01_00-EN.pdf?fileld-5546d4624933b875014974f4d97e09ea (retrieved online on 03.13.2024).

In bidirectional switching applications (AC switching) where it is necessary to switch both positive and negative currents or voltages, the common-source or common-emitter configuration (also referred to as a common-source or common-emitter circuit) is one of the most widely used circuit configurations; it is also referred to as a “back-to-back” configuration or circuit (AC=Alternating Current). An exemplary embodiment of such a common-source configuration is described in European patent application EP 1 271 743 A2 (Siemens AG) Jan. 2, 2003. The common-source or common-emitter configuration has the advantage, inter alia, that only a single control signal is required for both transistors, i.e. that a single-channel gate driver is sufficient for controlling the bidirectional semiconductor switch.

If there is a desire to use the advantages of the Kelvin terminal in the common-source or common-emitter configuration, in which two transistors are connected “back-to-back”, the Kelvin source or Kelvin emitter terminals of the two transistors must be connected to each other; they then form the reference potential of the gate driver. A standard circuit for gate control comprises a gate driver providing an output voltage or an output current, and at least one gate series resistor that can be used to adapt the switching behavior of the gate driver. This gate series resistor, as the name suggests, is usually located upstream of the gate terminal, but it is sufficient for adjusting the gate control if it is arranged anywhere in the gate control circuit. Since the Kelvin source terminal and the power source terminal are connected to each other inside the transistor, an auxiliary current path parallel to the load current path is now formed via the two Kelvin source terminals, see FIG. 2; a part of the main current flows through the auxiliary current path. The distribution of the current between the load current path and the auxiliary current path is essentially dependent on the internal properties of the semiconductor, e.g. the electrical resistances in the load current path and in the auxiliary current path. However, the auxiliary current path is not designed for high and lasting currents, and so manufacturers usually even advise against using the Kelvin terminals in common-source configurations.

However, an auxiliary current path cannot only arise in transistors with Kelvin source or Kelvin emitter terminals in a common-source or common-emitter circuit (“back-to-back” circuit), but in general in all common-source or common-emitter circuits. This is because, in a common-source or common-emitter circuit, the gate control circuit is always routed via the source or emitter terminal. Depending on the way in which the gate control circuit is connected to the source or emitter terminal, an auxiliary current path, which is not configured for the load current, may form in a common-source or common-emitter circuit, see FIGS. 3 to 5.

### SUMMARY OF THE INVENTION

The present invention is based on the object of providing an improved common-source or common-emitter configuration. For simplification, only the term common-source configuration is used below; it contains a back-to-back circuit of any two transistor types, in which the source or emitter terminals of the transistors are electrically connected to each other.

This object is achieved according to the invention by a common-source configuration having the features specified in the independent claim. The common-source configuration is a back-to-back interconnection of two transistors, in other words: a bidirectional semiconductor switch consisting of two transistors whose source or emitter terminals are electrically connected to each other. The common-source configuration has two control circuits for controlling one of the transistors each, i.e. a first of the two control circuits is designed to control a first one of the two transistors and a second of the two control circuits is designed to control a second one of the two transistors. The transistors are controlled in order to control a load current through the common-source configuration. The common-source configuration according to the invention is also referred to below as a bidirectional semiconductor switch or simply as a switch.

The common-source configuration of the two transistors has a main current path of the load current. In addition, the common-source configuration of the two transistors has an auxiliary current path of the load current, with the auxiliary current path running parallel to a section of the main current path. The auxiliary current path is formed by the interconnection of the two control circuits. One or more control series resistors are arranged in at least one of the control circuits. At least one of said control series resistors is arranged in the auxiliary current path. The at least one of the control series resistors is thus arranged in a section of the auxiliary current path which simultaneously forms a section of one of the control circuits.

According to the invention, a first transistor of the two transistors has a first source terminal, a first sink terminal and a first control terminal. A second transistor of the two transistors has a second source terminal, a second sink terminal and a second control terminal. The two source terminals are electrically connected. The two sink terminals and the two source terminals are in the main current path. A first control circuit of the control circuits, which is configured to control the first transistor, contains a first control unit, a first control series resistor and the first control terminal. A second control circuit of the control circuits, which is used to control the second transistor, contains a second control unit, a second control series resistor and the second control terminal. Running parallel to a section of the main current path is the auxiliary current path, one half of which is formed by a section of the first control circuit and the other half of which is formed by a section of the second control circuit.

The invention is based on the idea that a load current over the auxiliary current path is undesirable, since the auxiliary current path is not designed for the load current and can also form a disturbing resonant circuit: A major problem is the oscillation behavior of these two parallel current paths, the main current path and the auxiliary current path. The auxiliary current path is usually longer and thinner and therefore has a larger parasitic inductance. With the gate capacitance in the control circuit, this leads in many cases to an undesirable resonant circuit. Therefore, according to the invention, at least one control series resistor is arranged in the auxiliary current path: since the terminal pins themselves are designed to have as low an impedance as possible due to their internal structure (e.g. values <1 mOhm) and the control series resistors, which are also referred to as a gate series resistor, are usually in the one-digit to at most two-digit ohm range, only a relatively small, preferably negligible part of the load current thus flows over the auxiliary current path, but the by far greatest portion of the load current flows over the main current path designed for the load current.

The bidirectional semiconductor switch according to the invention is suitable for applications in which electrical current flows in both directions; it can therefore be used in AC applications, but also in DC applications with a bidirectional current flow (DC=Direct Current). The switch has two transistors. The transistors can be bipolar transistors, FET (e.g. MOSFET, JFET, SIT), IGBT, GTO, IGCT or other types of transistors. For the different transistor types, the electrical terminals of the transistor, which can be implemented by means of pins, wires or sheets protruding from the transistor housing, have different designations that are compared in table 1 for better understanding. Since the present invention can be executed with different transistor types without a specific transistor type being preferred, the generalized designations “source terminal”, “sink terminal” and “control terminal”, which are indicated in the first column of table 1, are used in this description of the invention for the electrical terminals of the transistor.

TABLE 1
Designations for the electrical terminals of 3-pin transistors

| | Bipolar | FET (MOSFET, | |
|---|---|---|---|
| Transistor | transistor | JFET, SIT, etc.) | IGBT |
| Source terminal | Emitter E | Source S | Emitter E |
| Sink terminal | Collector C | Drain D | Collector C |
| Control terminal | Base B | Gate G | Gate G |

Advantageous configurations and developments of the invention are specified in the dependent claims.

According to one preferred configuration of the invention, the first control unit and the second control unit are identical. The advantage here is that the control of the two transistors of the common-source configuration works with only a single control unit, e.g. a single-channel gate driver.

According to one preferred configuration of the invention, the two transistors are each configured as a 4-pin transistor and each have a control terminal, a sink terminal, and two source terminals, wherein a first of the source terminals is referred to as a power source terminal and a second of the source terminals is referred to as a Kelvin source terminal. The auxiliary current path is formed by the two Kelvin source terminals connected to each other.

The power source terminal and the Kelvin source terminal are two transistor terminals, both of which are electrically connected to the internal source terminal of the transistor (=emitter (bipolar transistor), =source (MOSFET), =emitter (IGBT)) at a branching point. This means that, even in the transistors with four terminals with which electrical contact can be made from the outside, the current or voltage is controlled by means of three internal terminals, but the internal source terminal of the transistor branches outward on its current path into two terminals, namely the power source terminal and the Kelvin source terminal. The branching point is always on the “bare die” of the transistor; otherwise it technically makes no sense.

Since the present invention can be executed with different 4-pin transistor types without a specific transistor type being preferred, the generalized designations “power source terminal”, “Kelvin source terminal”, “sink terminal” and “control terminal”, which are indicated in the first column of table 2, are used in this description of the invention for the four electrical terminals of the 4-pin transistors used according to the invention.

TABLE 2
Designations for the electrical terminals of 4-pin transistors

| | Bipolar | FET (MOSFET, | |
|---|---|---|---|
| Transistor | transistor | JFET, SIT, etc.) | IGBT |
| Power source | Power emitter E | Power source S | Power emitter E |
| terminal | | | |
| Kelvin source | Kelvin emitter E | Kelvin source S | Kelvin emitter E |
| terminal/Kelvin | | | |
| terminal | | | |
| Sink terminal | Collector C | Drain D | Collector C |
| Control | Base B | Gate G | Gate G |
| terminal | | | |

According to one preferred configuration of the invention, the Kelvin source terminals of the two 4-pin transistors are electrically connected to each other. The two 4-pin transistors are therefore interconnected in a way that is usually referred to as a common-source configuration.

According to one preferred configuration of the invention, at least one control series resistor is arranged in the electrical connection of the Kelvin source terminals. In the prior art, i.e. in a conventional common-source configuration, common (“standard”) wiring of the control terminal (often referred to as “gate wiring”) essentially contains a series connection of a control terminal driver (=voltage source), a control series resistor (also referred to as “control terminal series resistor” or “gate series resistor”) and the semiconductor control contact “control terminal”. The control series resistor can be used to optimize the way in which the semiconductor control contact “control terminal” is controlled by the control terminal driver.

According to one preferred configuration of the invention, these control series resistors are now removed from the wiring of the control terminals, where they are arranged in a conventional common-source configuration, and instead are moved into the electrical connection of the Kelvin source terminals. The movement of the control series resistors from the control terminals to the Kelvin source terminals according to the invention does not change the voltage ratios mathematically. Only the reference point (GND) of the control terminal driver is now no longer at the common source potential, but at the virtual GND potential downstream of the control series resistors, which could now also be called source terminal series resistors because of their relocation.

The preferred configuration of the invention is based on the finding that a movement of the control series resistors from the control terminals to the Kelvin source terminals does not change the voltage ratios, but allows the load current in the main current path to rise and allows the load current in the parallel auxiliary current path to decrease.

If the auxiliary current path through the Kelvin source terminals, which runs parallel to the main current path, the so-called “Kelvin path”, is considered, it is determined that, according to one preferred configuration of the invention, the two control series resistors are in this auxiliary current path. This results in a significantly higher total resistance in the Kelvin path compared to the electrical resistance in the current path through the power source terminals, the so-called “main current path”, since the terminals themselves—both the Kelvin source terminals and the power source terminals—are designed to have a relatively low impedance due to their internal structure (e.g. with resistance values<1 milliohm: The Kelvin source terminals have much thinner bonding wires than the bonding wires of the power source terminals. They therefore do not have as low an impedance as possible, but have as low an impedance as necessary.) and the control series resistors usually have resistance values that are in the one-digit to at most two-digit ohm range. For example, if it is assumed that the Kelvin source terminal of a transistor and the power source terminal of a transistor each have a resistance of 1 milliohm and that the control series resistor of a transistor has a resistance value of 1 ohm, this results, with two resistors connected in series, in a resistance in the auxiliary current path (“Kelvin path”) that is approximately 2000 times or more higher than in the main current path, which is why a maximum of two thousandths of the load current also flows through the parallel current path. Thus, no significant portion of the load current flows through the Kelvin source terminals any more, and therefore there is also no fear of any overloading of the Kelvin source terminals, even though the advantages of the Kelvin source terminals in terms of the switching behavior are preserved.

An essential advantage of the preferred configuration of the invention is therefore that the advantages of the Kelvin terminals can also be used for AC semiconductor switches and bidirectional DC semiconductor switches in a common-source configuration with Kelvin terminals, without having to accept any overloading of the semiconductor: The load current over the auxiliary current path parallel to the main current path through the two Kelvin source terminals, the so-called “Kelvin path”, is significantly reduced.

According to one preferred configuration of the invention, the electrical resistance in the auxiliary current path is at least ten times greater than the electrical resistance in the main current path due to the at least one control series resistor arranged in the auxiliary current path. It is advantageous that the load current over the auxiliary current path parallel to the main current path is significantly reduced compared to the load current through the main current path.

According to one preferred configuration of the invention, the electrical resistance in the electrical connection of the Kelvin source terminals is at least ten times greater than the electrical resistance in the electrical connection of the power source terminals. It is advantageous that the load current over the current path parallel to the main current path through the two Kelvin source terminals (“Kelvin path”) is significantly reduced compared to the load current through the main current path.

According to one preferred configuration of the invention, the electrical resistance in the auxiliary current path is at least one thousand times greater than the electrical resistance in the main current path due to the at least one control series resistor arranged in the auxiliary current path. It is advantageous that the load current over the auxiliary current path parallel to the main current path becomes negligibly small compared to the load current through the main current path.

According to one preferred configuration of the invention, at least one of the transistors is a MOSFET, an IGBT or a bipolar transistor. It is advantageous here that conventional and therefore cost-effective transistors can be used.

According to one preferred configuration of the invention, the electrically connected control terminals are connected to a control terminal driver. It is advantageous here that a single-channel gate driver is sufficient for controlling the bidirectional semiconductor switch.

According to one preferred configuration of the invention, a control terminal driver common to the two control circuits is arranged in the two control circuits, i.e. the two control circuits share the same control terminal driver (=gate driver). It is advantageous here that a single-channel gate driver, which is more cost-effective than a two-channel gate driver, is sufficient for controlling the bidirectional semiconductor switch.

Other features which are considered as characteristic for the invention are set forth in the appended claims.

Although the invention is illustrated and described herein as embodied in a common-source configuration of two transistors, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

The above-described properties, features and advantages of this invention and the way in which they are achieved will become clearer and more clearly understandable from the following description of the exemplary embodiments, which are explained in more detail with reference to the drawings, in each of which, schematically and not to scale:

FIG. 1 is a schematic diagram of a 4-pin transistor according to the prior art;

FIG. 2 is a schematic diagram of a common-source configuration with two 4-pin transistors and one gate series resistor each in the two gate control circuits according to the prior art;

FIG. 3 is a schematic diagram of the common-source configuration with two 4-pin transistors and a common gate series resistor for both gate control circuits according to the prior art;

FIG. 4 is a schematic diagram of a “simple” common-source configuration with two 3-pin transistors according to the prior art;

FIG. 5 is a schematic diagram of an “improved” common-source configuration with two 3-pin transistors and one gate series resistor each in the two gate control circuits according to the prior art;

FIG. 6 is a schematic diagram of an “improved” common-source configuration from FIG. 5 with a common gate series resistor for both gate control circuits according to the prior art;

FIG. 7 is a schematic diagram a common-source configuration according to the invention with two 4-pin transistors according to the invention;

FIG. 8 is a schematic diagram of a common-source configuration according to the invention with two 3-pin transistors according to the invention;

FIG. 9 is a perspective view of a MOSFET in the TO-247-4 design according to the prior art;

FIG. 10 is a perspective view of a MOSFET in the TO-247-3 design according to the prior art;

FIG. 11 is a schematic diagram of a 3-pin IGBT with a diode according to the invention;

FIG. 12 is a schematic diagram of a 4-pin IGBT with a diode according to the invention; and

FIG. 13 is a schematic diagram of a common-source configuration according to the invention with two 3-pin transistors according to the invention, wherein the configuration contains a first control unit and a second control unit.

### DETAILED DESCRIPTION OF THE INVENTION

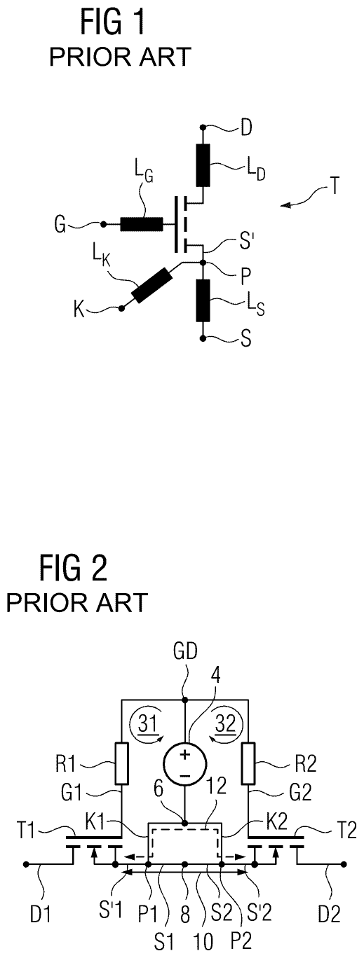

Referring now to the figures of the drawings in detail and first, particularly to FIG. 1 thereof, there is shown a conventional 4-pin transistor T, i.e. a transistor with a Kelvin source terminal K. The transistor shown is a MOSFET. In addition to the Kelvin source terminal K, the transistor T naturally has a sink terminal D (“drain”), a power source terminal S (“source”) and a control terminal G (“gate”). Each of the four transistor terminals D, G, K, S has a non-vanishing parasitic inductance L: in FIG. 1, the inductances of the terminals D, G, K, S are symbolized by the electrical symbol for inductance (“conductor loops”) and are marked with the reference signs Lx, where x is respectively replaced by one of the reference signs D, G, K, S of the terminals. The Kelvin source terminal K and the power source terminal S are electrically connected to the internal source terminal S′ of the transistor at a branching point P. This means that, even in transistors with four terminals with which electrical contact can be made from the outside, the current or voltage is controlled by means of only three internal terminals, but the internal source terminal S′ of the transistor T branches outward, to the terminals K and S, on its current path into two terminals, namely the power source terminal S and the Kelvin source terminal K. The MOSFET transistor T intrinsically has a body diode.

FIG. 2 shows a conventional bidirectional semiconductor switch in a common-source configuration with two 4-pin transistors, here: a MOSFET, and one gate series resistor each in the two gate control circuits. The bidirectional semiconductor switch has two 4-pin transistors T1, T2, a first 4-pin transistor T1 and a second 4-pin transistor T2. The transistors each have a control terminal G1, G2, a sink terminal D1, D2, a power source terminal S1, S2, and a Kelvin source terminal K1, K2. The control terminals G1, G2 of the two transistors T1, T2 are electrically connected at a control terminal contact point GD. The power source terminals S1, S2 of the two transistors T1, T2 are electrically connected at a power source terminal contact point 8. In addition, the Kelvin source terminals K1, K2 of the two transistors T1, T2 are electrically connected at a Kelvin source terminal contact point 6. The Kelvin source terminal K1 and the power source terminal S1 of the first transistor T1 are electrically connected to an internal source terminal S′1 of the first transistor T1 at a branching point P1 of the first transistor T1. The Kelvin source terminal K2 and the power source terminal S2 of the second transistor T2 are electrically connected to an internal source terminal S′2 of the second transistor T2 at a branching point P2 of the second transistor T2.

The electrically connected control terminals G1, G2 of the two transistors T1, T2 are electrically connected to a control terminal driver 4 (voltage source) at the control terminal contact point GD. In order to use the advantages of the Kelvin source terminals K1, K2, the two Kelvin source terminals K1, K2 are connected to each other at the Kelvin source terminal contact point 6 and form the reference potential of the control terminal driver 4, which provides the output voltage and the output current. Between the control terminal contact point GD and the transistor T1, T2, the control terminals G1, G2 each have a control series resistor R1, R2 that can used to adapt the switching behavior.

The control terminal driver 4 is also electrically connected to the electrically connected Kelvin source terminals K1, K2 of the two transistors T1, T2 at the Kelvin source terminal contact point 6. Thus, two control circuits 31, 32 with the control terminal driver 4 as a common voltage source result: a first control circuit 31 for controlling the first transistor T1 and a second control circuit 32 for controlling the second transistor T2.

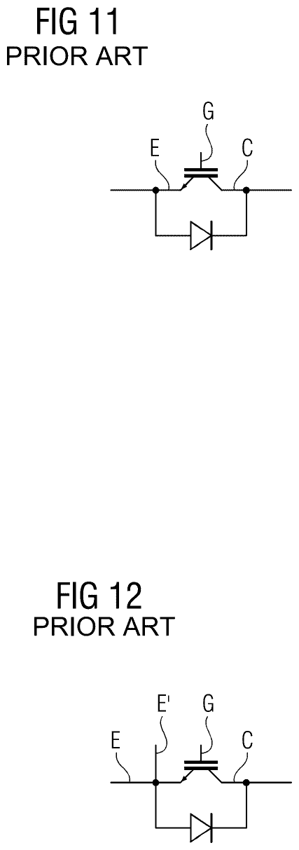

The diodes, which are connected in antiparallel with the transistors T1, T2 and are required for a bidirectional switch, are intrinsically present in the MOSFET. Only in the IGBT must these diodes be constructed from external components, since an IGBT does not have this diode intrinsically by virtue of its final P-channel layer; in this respect, reference is made to FIG. 11 and FIG. 12.

The bidirectional semiconductor switch conducts a load current between the two sink terminals D1, D2 on two parallel current paths: On the one hand, on a main current path 10, which comprises the power source terminals S1, S2 connected to each other at the power source terminal contact point 8. On the other hand, on an auxiliary current path=Kelvin path 12, which contains the Kelvin source terminals K1, K2 connected to each other at the Kelvin source terminal contact point 6.

The distribution of the load current depends mainly on the internal properties (e.g. resistances) of the bidirectional semiconductor switch. However, the Kelvin path 12 is not designed for high and lasting currents, and so manufacturers of 4-pin transistors usually even advise against using the Kelvin source terminals K1, K2 of the two transistors T1, T2 in a common-source configuration. Technically, it therefore works not to use the Kelvin source terminals K1, K2, as a result of which, of course, the positive effects that can be achieved by using the Kelvin source terminals K1, K2 also become obsolete. However, the bigger problem with the auxiliary current path=Kelvin path 12 is that it can form a disturbing resonant circuit.

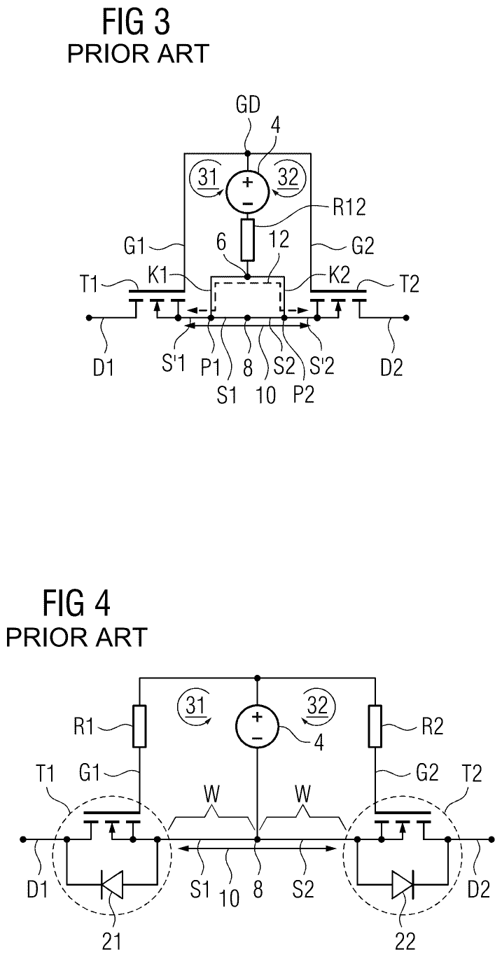

FIG. 3 shows, analogously to FIG. 2, an alternative known common-source configuration with two 4-pin transistors. In contrast to the common-source configuration shown in FIG. 2, in which each of the control circuits 31, 32 has its own control series resistor R1, R2, the common-source configuration shown in FIG. 3 has a common control series resistor R12 for both control circuits 31, 32. Apart from this, the common-source configurations shown in FIG. 2 and FIG. 3 are identical.

FIG. 4 shows a known “simple” common-source configuration with two 3-pin transistors T1, T2. These are MOSFETs: the explicitly depicted diodes 21, 22 symbolize the body diodes intrinsically present in the MOSFET. The two source terminals S1, S2 of the transistors T1, T2 are electrically connected at the source terminal contact point 8. The two gate terminals G1, G2 of the transistors T1, T2 are each arranged in a control circuit 31, 32, each with a separate control series resistor R1, R2. The two control circuits 31, 32 are supplied with voltage by a common control terminal driver 4. The control circuits 31, 32 each run from the control terminal driver 4 via the source terminal contact point 8 to the two source terminals S1, S2 and from there via the gate terminals G1, G2 back to the control terminal driver 4. A major disadvantage, which speaks against this “simple” circuit, is that the routes w of the control circuits 31, 32, which coincide with the main current path 10, are relatively long: since there is a significant inductance per unit length on these routes w, the switching behavior of the control circuits 31, 32 is significantly deteriorated. Exactly this provides the motivation to disconnect the main current path 10 from the control circuits 31, 32 as early as possible, as shown in FIG. 5. And exactly this is also an incentive to equip transistors with a Kelvin source.

FIG. 5 shows a known “improved” common-source configuration with two 3-pin transistors and one control series resistor R1, R2 each in the two control circuits 31, 32. The improvement in the common-source configuration shown in FIG. 5 compared to the common-source configuration shown in FIG. 4 is that the routes w of the control circuits 31, 32, which coincide with the main current path 10, have been shortened. In this way, the inductance in the control circuits 31, 32 has been reduced and thus their switching behavior has been improved. The routes w were shortened by dividing the previously common section of the control circuits 31, 32 between the GND (−) of the control terminal driver 4 and the main current path 10 at a branching point 7 into two separate individual branches of the control circuits 31, 32, which then each encounter the main current path 10 at a separation point 9. In this way, an auxiliary current path 12 of the load current is created by the two separate individual branches of the control circuits 31, 32, which each extend between the branching point 7 and the separation point 9.

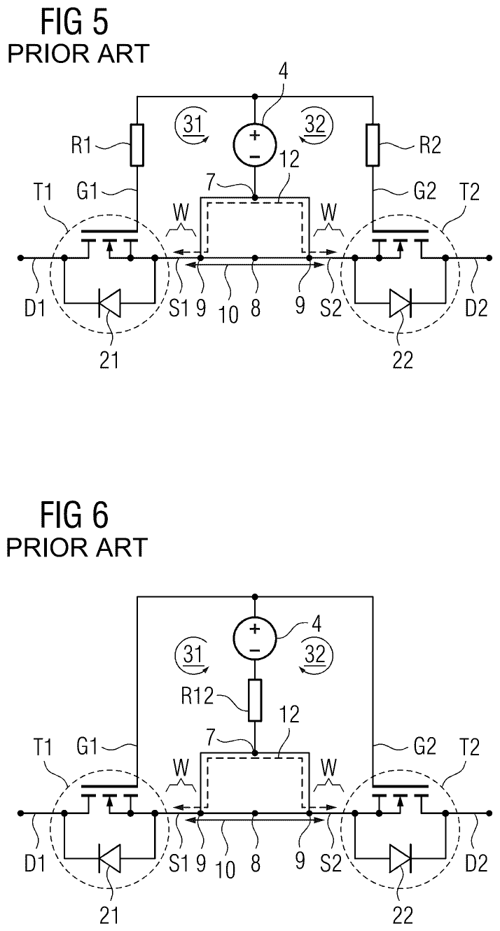

FIG. 6 shows the known “improved” common-source configuration from FIG. 5 with a common control series resistor for both control circuits 31, 32. In contrast to the common-source configuration shown in FIG. 5, in which each of the control circuits 31, 32 has its own control series resistor R1, R2, the common-source configuration shown in FIG. 6 has a common control series resistor R12 for both control circuits 31, 32. Apart from this, the common-source configurations shown in FIG. 5 and FIG. 6 are identical.

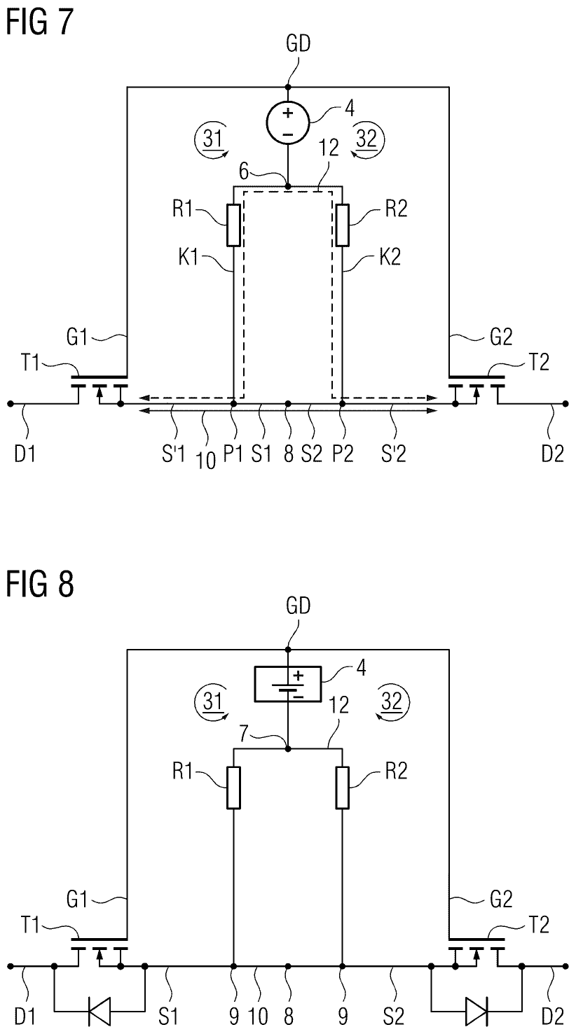

FIG. 7 shows a bidirectional semiconductor switch according to the invention in a common-source configuration with two 4-pin transistors. It largely corresponds to the conventional bidirectional semiconductor switch in a common-source configuration, as shown in FIG. 2, but with the decisive difference that the control series resistors R1, R2 are arranged in the auxiliary current path 12. As a result of the control series resistors R1, R2 in the auxiliary current path 12, only a relatively small, preferably negligible part of the load current thus flows over the auxiliary current path 12, but the by far greatest portion of the load current flows over the main current path 10 designed for the load current. Thus, no significant load current flows through the auxiliary current path=Kelvin path 12 any more, and therefore there is also no fear of any overloading of the Kelvin source terminals K1, K2; nevertheless, the advantages for the switching behavior that can achieved by using the Kelvin source terminals K1, K2 are preserved.

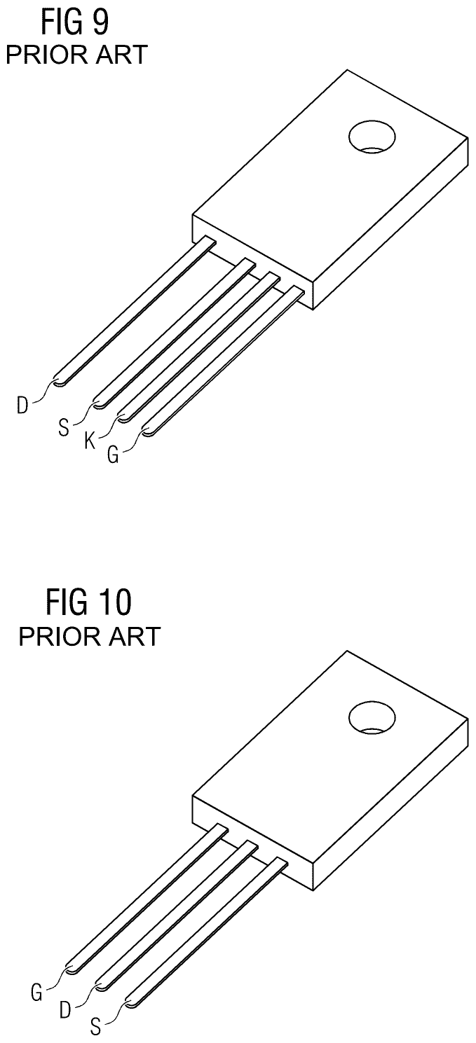

FIG. 8 shows a common-source configuration according to the invention with two 3-pin transistors. In order to recognize the feature of this common-source configuration according to the invention that is essential to the invention, it is to be compared with the known “improved” common-source configuration shown in FIG. 5. The common-source configuration shown in FIG. 8 corresponds largely to the conventional common-source configuration shown in FIG. 5, but with the decisive difference that the control series resistors R1, R2 are arranged in the auxiliary current path 12. As a result of the control series resistors R1, R2 in the auxiliary current path 12, only a relatively small, preferably negligible part of the load current thus flows over the auxiliary current path 12, but the by far greatest portion of the load current flows over the main current path 10 designed for the load current.

FIG. 9 shows a known 4-pin MOSFET in the design with a TO-247-4 housing. The 4-pin MOSFET has a Kelvin source terminal K, a sink terminal D (“drain”), a power source terminal S (“source”) and a control terminal G (“gate”).

FIG. 10 shows a known 3-pin MOSFET in the design with a TO-247-3 housing. The 3-pin MOSFET has a sink terminal D (“drain”), a source terminal S (“source”) and a control terminal G (“gate”).

FIG. 11 shows a circuit diagram of a known 3-pin IGBT with a separate freewheeling diode; whereas a MOSFET intrinsically has a body diode, an IGBT which does not have an intrinsic diode must be separately equipped with a diode if it requires a bidirectional application. Such a 3-pin IGBT can be housed in a TO-247-3 housing. The 3-pin IGBT has a sink terminal C (“collector”), a source terminal E (“emitter”) and a control terminal G (“gate”).

FIG. 12 shows a circuit diagram of a known 4-pin IGBT with a separate freewheeling diode. Such a 4-pin IGBT can be housed in a TO-247-4 housing. The 4-pin IGBT has a Kelvin source terminal E′ (“Kelvin emitter” or “auxiliary emitter”), a power source terminal E (“emitter”), a sink terminal C (“collector”) and a control terminal G (“gate”).

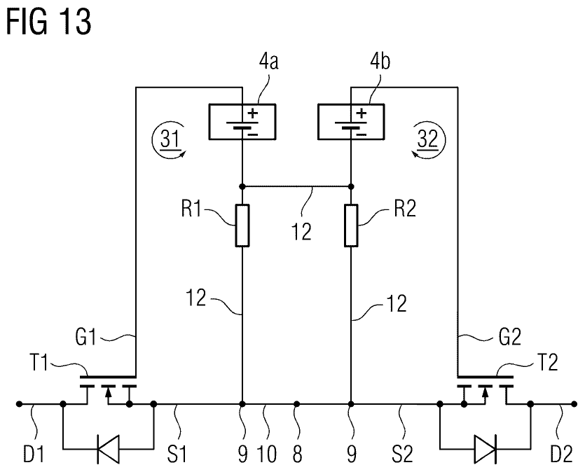

FIG. 13 shows a common-source configuration according to the invention with two 3-pin transistors T1, T2. In order to recognize the feature of the common-source configuration according to the invention that is essential to the invention, it is to be compared with the known “improved” common-source configuration shown in FIG. 5. The common-source configuration shown in FIG. 13 corresponds largely to the conventional common-source configuration shown in FIG. 5, but with the first decisive difference that the control series resistors R1, R2 are arranged in the auxiliary current path 12. As a result of the control series resistors R1, R2 in the auxiliary current path 12, only a relatively small, preferably negligible part of the load current thus flows over the auxiliary current path 12, but the by far greatest portion of the load current flows over the main current path 10 designed for the load current. A second decisive difference is the fact that the first control circuit 31 used to control the first transistor T1 contains a first control unit 4a, and the second control circuit 32 used to control the second transistor T2 contains a second control unit 4b. The configuration of FIG. 13 with two separate control units 4a, 4b is to be compared with the configuration of FIG. 8 with a common single shared control unit 4.

The following is a summary list of reference numerals and the corresponding structure used in the above description of the invention:
4 Control terminal driver
4a Control terminal driver
4b Control terminal driver
6 Kelvin source terminal contact point
7 Branching point of GND
8 Power source terminal contact point, source terminal contact point
9 Main current path-control circuit separation point
10 Main current path
12 Auxiliary current path
21 Diode
22 Diode
31 Control circuit
32 Control circuit
D Sink terminal of T
D1 Sink terminal of T1
D2 Sink terminal of T2
GD Control terminal contact point
G Control terminal of T
GND Ground
G1 Control terminal of T1
G2 Control terminal of T2
K Kelvin source terminal of T
K1 Kelvin source terminal of T1
K2 Kelvin source terminal of T2
LD Inductance of D
LG Inductance of G
LK Inductance of K
LS Inductance of S
P Branching point of T
P1 Branching point of T1
P2 Branching point of T2
R1 Control series resistor of T1
R2 Control series resistor of T2
S Power source terminal of T
S1 Power source terminal of T1
S2 Power source terminal of T2
S′ Internal source terminal of T
S′1 Internal source terminal of T1
S′2 Internal source terminal of T2
T Transistor
T1 First transistor of the bidirectional semiconductor switch
T2 Second transistor of the bidirectional semiconductor switch

1. A common-source configuration, comprising:
two transistors;
two control circuits each controlling one of said transistors in order to control a load current through the common-source configuration;
a main current path of the load current;
an auxiliary current path of the load current running parallel to a section of the main current path;
said two transistors include a first transistor having a first source terminal, a first sink terminal and a first control terminal and a second transistor having a second source terminal, a second sink terminal and a second control terminal, wherein said first and second source terminals are electrically connected, wherein said first and second sink terminals and said first and second source terminals are in said main current path;
said two control circuits include a first control circuit used to control said first transistor and containing a first control unit, at least one first control series resistor and said first control terminal and a second control circuit used to control said second transistor and containing a second control unit, at least one second control series resistor and said second control terminal, wherein running parallel to a section of said main current path is said auxiliary current path, one half of said auxiliary current path is formed by a section of said first control circuit and another half of said auxiliary current path is formed by a section of said second control circuit; and
at least one control series resistor, selected from the group consisting of said at least one first control series resistor and said at least one second control series resistor, is disposed in said auxiliary current path.

2. The common-source configuration according to claim 1, wherein said first control unit and said second control unit are a common single shared control unit.

3. The common-source configuration according to claim 1, wherein:
said two transistors each have four terminals, including said control terminal, said sink terminal, said source terminal and a Kelvin source terminal; and
said auxiliary current path is formed by said two Kelvin source terminals connected to each other.

4. The common-source configuration according to claim 1, wherein an electrical resistance in said auxiliary current path is at least ten times greater than an electrical resistance in said main current path due said at least one control series resistor disposed in said auxiliary current path.

5. The common-source configuration according to claim 4, wherein the electrical resistance in said auxiliary current path is at least one thousand times greater than the electrical resistance in said main current path due to said at least one control series resistor disposed in said auxiliary current path.

6. The common-source configuration according to claim 1, wherein at least one of said transistors is a metal-oxide semiconductor field-effect transistor, an insulated gate bipolar transistor or a bipolar transistor.

7. The common-source configuration according to claim 1, wherein said first and second control units each function as a control terminal driver for said control circuits.

8. A common-source configuration, comprising:
two transistors;
two control circuits each controlling one of said transistors in order to control a load current through the common-source configuration;
a main current path of the load current;
an auxiliary current path of the load current running parallel to a section of the main current path;
said two transistors include a first transistor having a first source terminal, a first sink terminal and a first control terminal and a second transistor having a second source terminal, a second sink terminal and a second control terminal, wherein said first and second source terminals are electrically connected, wherein said first and second sink terminals and said first and second source terminals are in said main current path;
said two control circuits include a first control circuit used to control said first transistor and containing a common single shared control unit, a first control series resistor and said first control terminal and a second control circuit used to control said second transistor and containing said common single shared control unit, a second control series resistor and said second control terminal, wherein running parallel to a section of said main current path is said auxiliary current path, one half of said auxiliary current path is formed by a section of said first control circuit and another half of said auxiliary current path is formed by a section of said second control circuit; and
at least one control series resistor, selected from the group consisting of said at least one first control series resistor and said at least one second control series resistor, is disposed in said auxiliary current path.

9. The common-source configuration according to claim 8, wherein:
said two transistors each have four terminals, including said control terminal, said sink terminal, said source terminal and a Kelvin source terminal; and
said auxiliary current path is formed by said two Kelvin source terminals connected to each other.

10. The common-source configuration according to claim 8, wherein an electrical resistance in said auxiliary current path is at least ten times greater than an electrical resistance in said main current path due said at least one control series resistor disposed in said auxiliary current path.

11. The common-source configuration according to claim 10, wherein the electrical resistance in said auxiliary current path is at least one thousand times greater than the electrical resistance in said main current path due to said at least one control series resistor disposed in said auxiliary current path.

12. The common-source configuration according to claim 8, wherein at least one of said transistors is a metal-oxide semiconductor field-effect transistor, an insulated gate bipolar transistor or a bipolar transistor.

13. The common-source configuration according to claim 8, wherein said common single shared control unit functions as a control terminal driver for controlling said control circuits.
